(19) United States
(12) Patent Application Publication
(10) Pub. No.: US 2011/0216919 A1
(43) Pub. Date: Sep. 8, 2011

(54) ASSISTIVE-LISTENING SYSTEM AND METHOD FOR TELEVISION, RADIO & MUSIC SYSTEMS

(76) Inventor: Kenneth A. Ullrich, Wenatchee, WA (US)

(21) Appl. No.: 13/044,362

(22) Filed: Mar. 9, 2011

Related U.S. Application Data
(63) Continuation of application No. 11/746,495, filed on May 9, 2007, now abandoned.
Application No. 11/746,495 is a continuation of application No. 10/025,313, filed on Dec. 18, 2001, now abandoned.
Application No. 10/025,313 is a continuation of application No. 09/183,497, filed on Oct. 30, 1998, now abandoned.
(60) Provisional application No. 60/063,949, filed on Oct. 31, 1997.

(51) Int. Cl. H03G 3/00

(52) U.S. Cl. 381/104

(57) ABSTRACT

An assistive-listening system is used with sound-producing equipment that includes a signal source, and first and second sound sources operatively associated with the signal source and configured to produce sound corresponding to signals received from the signal source. The assistive-listening system includes a volume control operatively associated with the signal source and configured proportionally to change the volume of both the first and second sound sources. Also included is a support structure configured to support and position the second sound source so that a hearing-impaired listener may listen effectively to sound controlled by the volume control without disturbing normal-hearing listeners.

### CROSS-REFERENCE TO RELATED APPLICATIONS

This application is a continuation of U.S. patent application Ser. No. 11/746,495, filed May 9, 2007 and entitled “Assistive Listening System and Method for Television, Radio & Music Systems”, which application is a continuation of U.S. patent application Ser. No. 10/025,313, filed Dec. 18, 2001 and entitled “Assistive Listening System and Method for Television, Radio & Music Systems”, which is a continuation of U.S. patent application Ser. No. 09/183,497, filed Oct. 30, 1998, entitled “Assistive Listening System and Method for Television, Radio & Music Systems, which claims priority from U.S. Provisional Patent Application Ser. No. 60/063,949, filed Oct. 31, 1997 and entitled “Assistive Listening System and Method for Television, Radio & Music Systems”, the disclosures of which are incorporated herein by reference.

### TECHNICAL FIELD

The present Invention relates generally to the improvement of hearing and can be called an assistive listening device. More particularly, the invention relates to a novel sound delivery apparatus and method, which may consist of a portable speaker, stand, and wireless transmitter/receiver, amplifier, and volume/tone controls that present sound from a television primarily, but not to exclude radio, and music systems, to within less than an inch of the top and center of a listener's head, but not limited to this position, with the two purposes of improving the listener's comprehension of the sound source speech signal and increasing listener comfort by reducing the room sound intensity level.

### BACKGROUND AND SUMMARY OF THE INVENTION

Speech from television, radio, and music systems is often unintelligible to the listener in noisy home environments, when distances of more than 3 to 5 feet exist between the sound source and the listener, when the listening room is large and reverberant, and/or when the listener is elderly and/or hearing impaired. Many of us have experienced the frustration of missing key parts of news commentary and accented language programs due to competing sounds from sources such as automatic dish washers, running sink water, air conditioning fans, and others' conversations. Our typical reaction to this comprehension difficulty is to increase the sound intensity, often to levels that are uncomfortably loud and irritating to ourselves and others. Such difficulty with speech comprehension and the subsequent irritation from the increased intensity adjustment becomes especially frustrating in the close living quarters of apartments and nursing homes.

### RELATED ACOUSTICAL SCIENCE DISCUSSION

In addition to the listener's hearing ability and age, the comprehension of speech is affected by the intensity level of the sound, sound reflection and room reverberation, and background noise. The effect of each of these acoustical factors depends on the distance of the listener from the sound source. As distance increases comprehension decreases.

Intensity Level: For normal hearing listeners and for most hearing impaired listeners, the comprehension of speech decreases as the intensity of the speech decreases. See FIG. 1.

Sound Reflection and Reverberation: Sounds propagate from a source. Direct sound travels directly to the listener while indirect sound first strikes surrounding walls and objects and arrives at a listener's ears as much as seconds later. See FIG. 2. The intensity of the reflections depends on the construction materials of the room's boundaries and objects. Speech comprehension decreases as the ratio of direct to indirect sound decreases (Nábelek and Nábelek, 1994). The process of an indirect sound fading or decaying away with time is termed reverberation. Reverberation time increases with the volume of a room and greater reflective properties of walls and objects within the room. A sound that is directed into a sound absorbing material will obviously be less reverberant. It has been shown that speech intelligibility decreases as reverberation time increases (Helfer and Wilber, 1990).

Noise: Speech comprehension is affected by noise. The sources of noise in the home include others' conversation, heating and air conditioning mechanisms, and appliances such as dish and clothes washers. The overall effects of noise on speech perception can be inferred from the speech-to-noise ratio (S/N) expressed in dB. Speech comprehension is best when the S/N ratio is high and poorer when the S/N ratio is low (Finitzo-Hieber and Tillman, 1978). Because most consonant sounds are less intense than vowel sounds, (see FIGS. 3 & 4), they are less intelligible in noise. As the consonant sounds are relatively more important than the vowel sounds for comprehension, (see FIGS. 3 &4), the effects of noise become especially critical for individuals with high frequency hearing loss. This issue will receive further discussion.

Distance Between the Sound Source and the Listener: Speech sounds received at a greater distance from the sound source differ from the sounds received closer to the source. Distance affects speech intensity, sound reflection and reverberation (the ratio between direct and indirect sounds), and signal-to-noise ratio.

The Effect of Distance on Intensity: According to the inverse square law, the intensity of direct sound decreases by one half for each doubling of the distance from the sound source (Speaks, 1992). The effect of distance on sound intensity is shown in FIG. 5. Low frequencies, possessing an abundance of power, easily propagate to the listener, whereas high frequencies, having relatively little energy at the source, may arrive at the listener at intensity levels too small to comprehend. Unfortunately, it is these higher frequencies that are responsible for the majority of intelligibility (see FIGS. 3 & 4). The importance of the adequate high frequency transmission is more pronounced in persons suffering from the most common type of hearing loss and will receive discussion later on.

The Effect of Distance on Reflected Sound and Reverberation (Ratio Between Direct to Indirect Sound): Direct sound decreases with distance but indirect sound is distributed evenly throughout the room and is dependent upon the room volume and reverberation. Speech comprehension is directly proportional to the ratio of direct to indirect sound (Nábelek and Nábelek, 1994). Thus, as the direct sound intensity decreases with distance and the indirect sound remains the same, the comprehension of speech signal decreases.

The Effect of Distance on the Signal-to-noise Ratio: The intensity level of the speech signal declines with increased distance, whereas the intensity level of background noise is fairly homogeneously distributed throughout a room. Since speech comprehension decreases as the signal-to-noise ratio decreases, an increase in distance will reduce speech understanding in noise.

Hearing Impaired Listeners: All of the principles of room acoustics discussed above are applicable for hearing-impaired listeners. Additionally, hearing impaired listeners need higher speech intensity levels to maintain speech comprehension (Nábelek and Nábelek, 1994), and a higher speech signal-to-noise ratio and lower reverberation time to maintain speech comprehension, (Finitzo-Hieber and Tillman, 1978) as seen in FIG. 6. The loss of the high frequencies only is typical in the hearing impaired. Speech intensity is primarily the result of low frequency energy being received by the auditory system; speech comprehension is primarily the result of high frequency energy being received by the auditory system (see FIGS. 3 & 4). When distance exacerbates the loss of high frequency energy, the ratios of direct to indirect sound and signal-to-noise, and reverberation, the hearing impaired listener's only option is to increase the television, radio, or music system sound intensity. Although some increase in high frequency energy reception is gained, the greatest effect is in the increase of low frequency energies and results in excessive room sound intensity and uncomfortable loudness. This increase in low frequency energy also increases room reverberation; an increase in reverberation reduces speech signal comprehension.

Elderly Listeners: All of the principles of room acoustics and hearing discussed above are applicable for elderly listeners. Elderly listeners, like typical hearing-impaired listeners, have reduced high frequency hearing and normal low frequency hearing. Additionally, because of central auditory processing changes, elderly listeners need a higher speech intensity level to maintain speech comprehension (Plomp and Mimpen, 1979; Nábelek and Robinson, 1982), and a higher speech signal-to-noise ratio and lower reverberation time to maintain speech comprehension (Bergman et al, 1976; Duquesnoy and Plomp, 1980; Helfer and Wilber, 1990, Nábelek and Robinson, 1982). The comprehension reduction starts in the fourth decade of life (Nábelek and Nabelet, 1994).

Existing Assistive Listening Devices: All existing assistive listening devices that improve speech understanding of television, radio, and music systems have auditory weaknesses and/or operational inconveniences. The most acoustically beneficial listening device is the over-the-ear or in-the-ear earphone coupled electronically to the sound source by wire or wireless infrared/FM transmitter/receiver. Although this device delivers excellent sound quality to the listener and reduces background noise by occluding the ears and eliminating reverberation, the occluding earphone cushions isolate the listener from important environmental signals such as telephone rings and doorbells and from family communications. Additional difficulties include the danger of tripping on the signal delivery cord which runs from the sound source to the listener, the inconvenience of batteries which power the wireless systems (low intensity and signal distortion from a weak charge, replacement), the discomfort when reclining against a chair cushion or pillow, misshaping the hair if headbands are used, and the high risk of damage to the earphone from sitting or rolling over on it.

The most common assistive listening device for the hearing impaired is the hearing aid. Although the hearing aid does improve listener understanding of speech by amplifying selected frequencies which correspond to the hearing loss, users and researchers continue to report listening comprehension difficulties in adverse listening conditions. Regardless of hearing aid circuit sophistication, unless the hearing aid is directly wired to the sound source, the sound signal input to a hearing aid microphone contains speech, indirect sounds, and noise; amplification of speech also amplifies the others.

Accordingly, it is a principal object of the present invention to provide apparatus and method to overcome listener comprehension limitations for television, radio, and music systems:

1. The apparatus and method will reduce the distance between the source of the sound and the listener, thereby improving speech signal comprehension by:

a. Increasing the intensity of the high frequencies according to the inverse square law;

b. Increasing the direct to indirect sound ratio and reducing reverberation; and

c. Increasing the signal-to-noise ratio.

2. The apparatus and method will improve listener comprehension of the speech signal by further reducing speech sound reverberation. Reverberation will be further reduced by directing the speech sound signal generally downward onto the sound-absorbing surfaces of the listener's body, chair or couch furniture, and carpet rather than the typical direction of the sound which is towards reflective walls and ceiling.

3. The apparatus and method will improve listener and family member listening room comfort by reducing listening room sound intensity levels. Listening room sound intensity levels will be less because the apparatus and method deliver an improved speech sound signal by presenting the sound source signal closer to the listener's head in a generally downward direction, thereby providing an abundance of high frequency energy (see inverse square law above), improved direct-to-indirect signal ratio, less reverberation, and improved signal-to-noise ratio, without needing to increase the television, radio, or music system sound source intensity level.

4. The apparatus and method may allow the listener to adjust the sound signal intensity and frequency shaping adjustment without the listener leaving his seat.

5. The apparatus may be portable.

6. The apparatus and method may be adjustable about the horizontal, vertical, and lateral axes.

7. The apparatus and method may be used with any standard television, radio, or music system. The apparatus and method may connect to the sound source with the use of a hardwire connection or microphone.

8. The apparatus and method may allow for the adjustment of sound signal intensity level and frequency shape independently of the television, radio, and music sound source.

9. The apparatus and method will not affect the normal use of the television, radio, and music sound system.

10. The apparatus and method may present the sound signal to both ears. In quiet and difficult listening conditions, speech signal comprehension is improved when both ears receive the sound signal including the majority of those individuals with hearing loss (Nábelek and Robinson, 1982; Nábelek and Pickett, 1974; Plomp, 1976; Neuman and Hochberg, 1983).

Additionally it is a principal object of the present invention to provide apparatus and method that overcome the drawbacks of prior art assistive listening devices.

1. The apparatus and method will not occlude the listener's ears and consequently isolate the listener from important environmental sounds and the communications of family.

2. The apparatus and method may be wireless and may employ an infrared or FM transmitter/receiver.

3. The apparatus and method may be free of the inconveniences of batteries and rechargers and be powered by standard 115-volt house current.

4. The apparatus and method will not encumber the head and ears of the listener who wishes to recline and rest the head and ears against a chair or pillow as no part of the apparatus touches the ears and/or head.

5. The apparatus and method will not misshape hair.

6. The apparatus may employ a stand, permitting the apparatus to be positioned above and behind or to either side of the listener and minimizing the chances that the apparatus will be damaged by sitting.

7. The apparatus and method will compliment the use of hearing aids by providing an improved speech signal for hearing aid processing and thus improving speech signal comprehension.

8. The apparatus and method will provide some hearing aid users an opportunity to rest from the use of the hearing aid or aids as the apparatus and method may provide increased sound signal intensity and frequency shaping and in so doing may serve as a substitute for the hearing aid or aids.

### BRIEF DESCRIPTION OF THE TABLES AND FIGURES

Table 1 provides information from the inventor's research study, showing the age and the three frequency pure tone hearing acuity average for each listener's ear in the research study.

Tables 2a and 2b shows listening comprehension test scores for each listener in the research study.

Tables 3a and 3b shows room sound intensity measurements for the room used in the research study.

FIG. 1 is a plot of performance-intensity functions versus sound pressure for normal ear, conductive loss, cochlear site of lesion, and retrocochlear site of lesion. (Source: National Institute for Hearing Instrument Studies 1993; page 13-3).

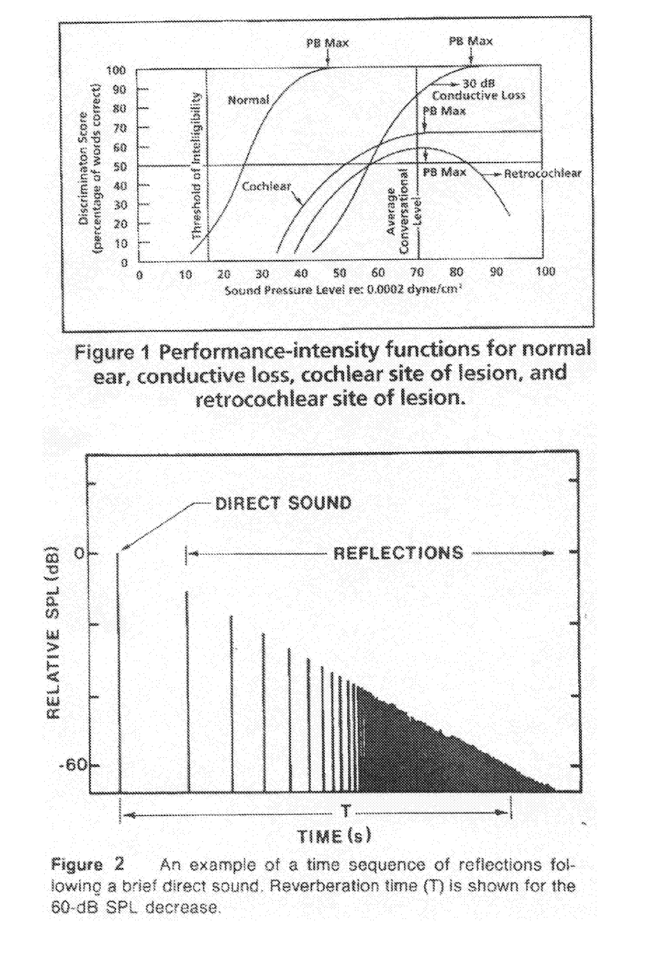

FIG. 2 is a graph of relative SPL versus time showing the time sequence of reflections following a brief direct sound. (Source: Handbook of Clinical Audiology, Fourth Edition, Katz, 1994; page 625).

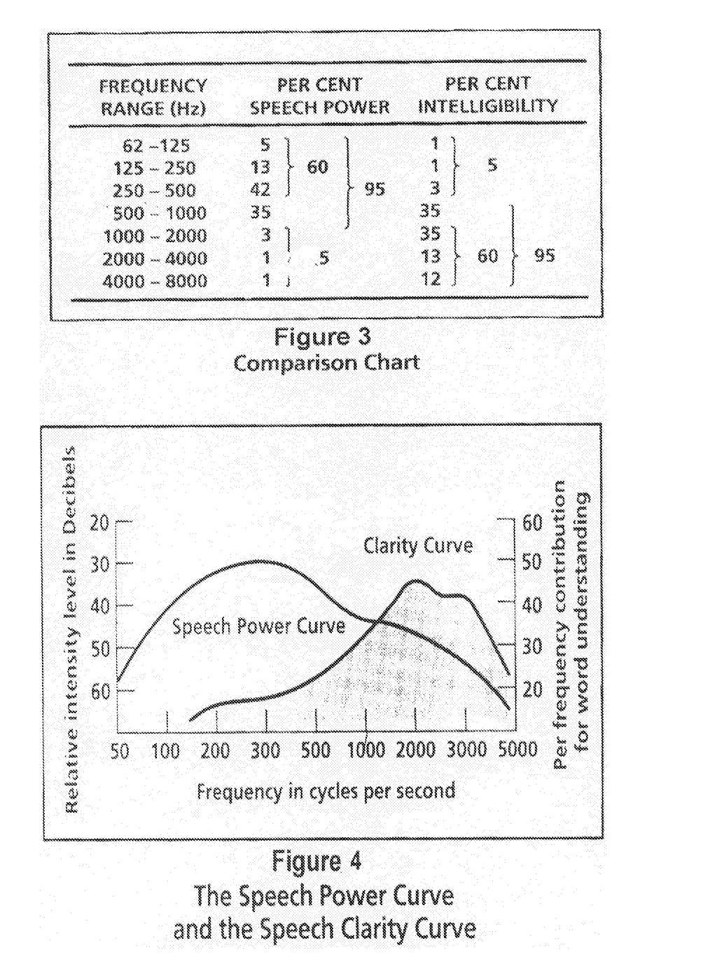

FIG. 3 is a table showing percent speech power and percent intelligibility as a function of frequency range. (Source: National Institute for Hearing Instrument Studies 1993; page 15-4).

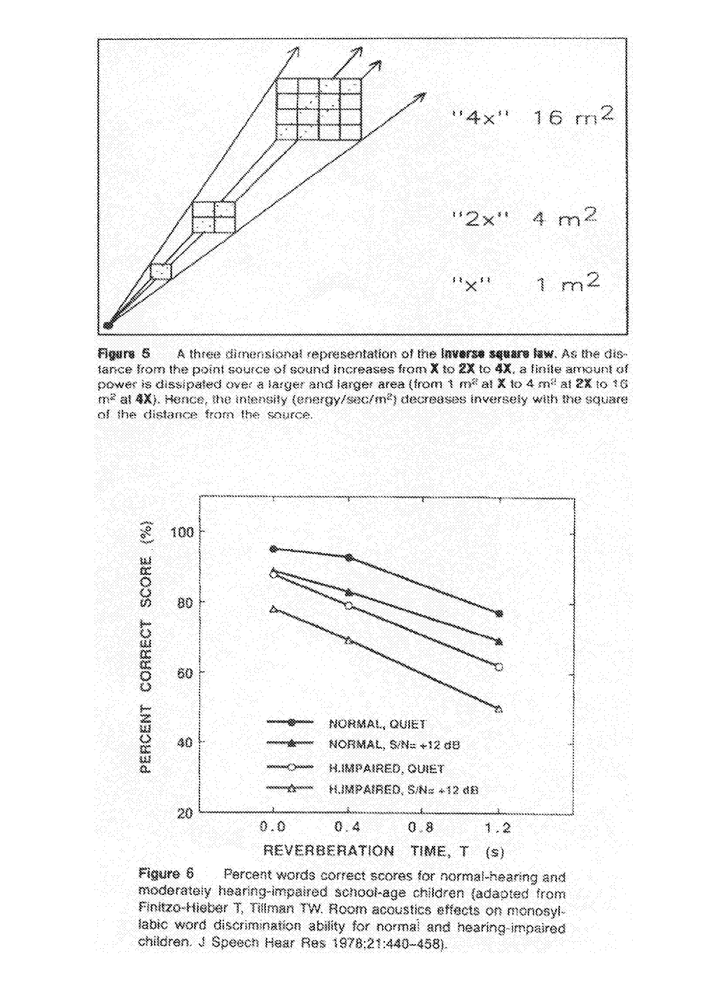

FIG. 4 is a graph of relative intensity level versus frequency for the speech power curve and the speech clarity curve. (Source: Introduction to Sound, Speaks, 1992; page 261).

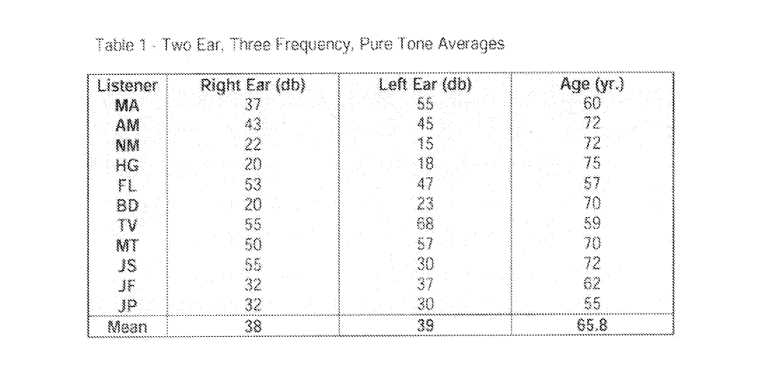

FIG. 5 is a three-dimensional representation of the inverse-square law. (Source: National Institute for Hearing Instrument Studies 1993; page 15-4).

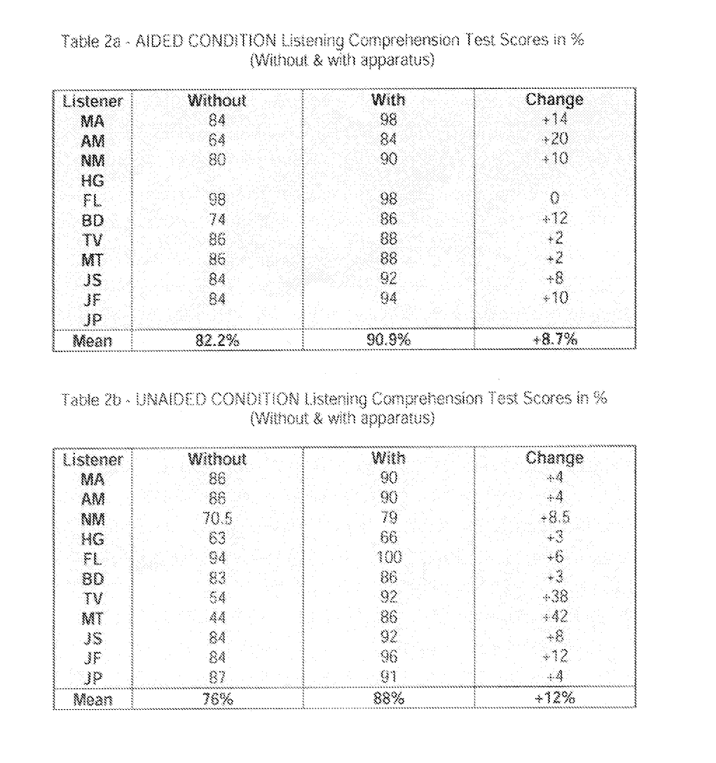

FIG. 6 is a graph of percent correct score versus reverberation time for normal-hearing and moderately hearing-impaired school-age children. (Source: Handbook of Clinical Audiology, Fourth Edition, Katz, 1994; page 631).

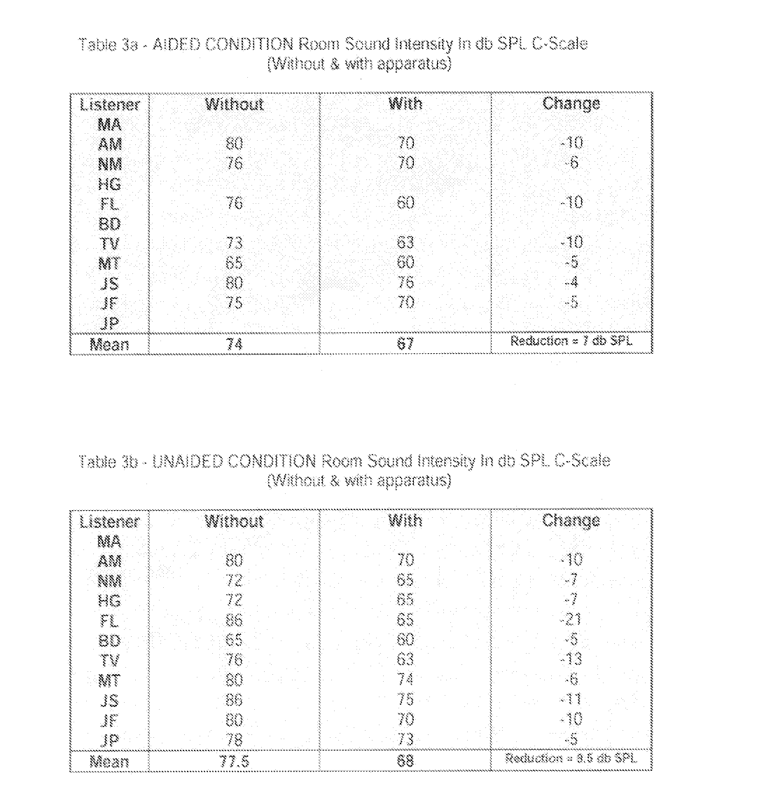

### DETAILED DESCRIPTION OF PREFERRED EMBODIMENT AND BEST MODE OF CARRYING OUT THE INVENTION

The device consists of two parts. Part one is the wireless transmitter, either infrared or FM. The wireless transmitter connects to the television, radio, or music sound source. The connection is best accomplished by hardwire directly to an audio output jack. However, if no audio output jack exists, the wireless transmitter can receive audio input from an accessory microphone, which connects to a transducer (speaker) grill. The wireless transmitter is powered by standard US 115-volt house current. Part two consists of the wireless receiver, amplifier, sound intensity and frequency shaping controls, transducer (speaker), flexible support tubing, and vertical floor stand and power supply. The wireless receiver, amplifier, and sound intensity and frequency shaping controls may be placed in a separate enclosure depending upon speaker enclosure requirements. The transducer (speaker) enclosure should be center positioned as close to the top of the head as possible to maximize the acoustical benefits of the apparatus. The vertical stand can be positioned behind, left or right of the listener. Part Two may be powered by standard US 115-volt house current. Part two may feature a magnetic induction transmitter for hearing aid users whose hearing aids are equipped with magnetic induction receivers for private and/or sound quality demands. Part two may feature an audio output jack for the use of earphones for private listening and sound quality demands.

### Research

Listener speech signal comprehension and listening room intensity levels were evaluated with eleven listener subjects in their private homes. Listener subjects ranged in age from 55 to 75 years with a mean of 65.8 years. All listener subjects were judged to be capable of understanding the test instructions and capable of reliable attending and reporting. All listener subjects reported documented hearing loss and each provided their most current audiogram. Eight of the listener subjects actively use hearing aids. The age and the three frequency pure tone hearing acuity average for each ear are shown for each listener subject in Table 1.

Ambient noise levels in each home were judged to be consistently quiet throughout each test session. In one test session, the listening subject's dog began to bark while dreaming; the dog was put out and the test was re-administered with a new word list. Each test was administered with the listener subject seated in their most frequently used television-viewing chair.

A videotape of the author presenting two listening comprehension word list tests was administered first without and then with the apparatus. The listener test subject was instructed to listen intently to each presented word and to then repeat the word as heard. The author then judged the word to be correct or incorrect. Each word list test consisted of fifty single syllable words from the Northwestern University (NU 6), lists 1A, 2A, and 3A. List 3A was used if a repeat test was needed. The NU 6 list 3 Forms A-D were used for several listening test subjects. Listening test subjects with hearing aids were tested in the aided and then unaided condition, without and then with the apparatus. The listening comprehension test scores are displayed in Tables 2a and 2b. Before the first word list test was administered, the listener test subject was instructed to adjust the television speaker sound to a comfortable and comprehensible intensity level as an introductory running speech sample was played through the video player and television speaker. The sound intensity level of the room was then measured with a General Radio model 1565-B sound level meter (C scale) at a position approximately 1 meter from the television speaker. A room sound intensity measurement was similarly taken with the apparatus in operation. For this measurement the apparatus was first adjusted to a comfortable and comprehensible level and the television sound speaker adjusted to a complimentary level. For this condition, several listener test subjects preferred that the television speaker be turned completely off, relying solely on the sound from the apparatus. The room sound intensity measurements are displayed in Table 3.

### Test Results Summary

The apparatus and method improved aided listener test subject comprehension differences by an average 8.7 percent. The apparatus and method improved the unaided test subject comprehension differences by an average 12 percent. Each listener test subject in the aided and unaided conditions experienced improved listening comprehension; two subjects experienced improved differences of 38 and 42 percent.

The apparatus and method-reduced room sound intensity levels in the aided condition by an average 7 dB SPL C scale. The apparatus and method reduced room sound intensity levels in the unaided condition by an average 9.5 dB SPL C scale. Room sound intensity levels in the aided and unaided conditions were reduced for each listener test subject.

While the present invention has been shown and described with reference to the foregoing preferred embodiment, it will be apparent to those skilled in the art that other changes in form and detail may be made therein without departing from the spirit and scope of the invention as described further below.

I claim:

1. An assistive-listening system for use with sound-producing equipment, the sound-producing equipment including a signal source and first and second sound sources operatively associated with the signal source and configured to produce sound corresponding to signals received from the signal source, the assistive-listening system comprising:
a volume control operatively associated with the signal source and configured to proportionally change the volume of both the first and second sound sources; and
a support structure configured to support and position the second sound source so that a hearing-impaired listener may listen effectively to sound controlled by the volume control without disturbing normal-hearing listeners.

2. The assistive-listening system of claim 1, wherein the support structure positions the second sound source such that it is closer to the hearing-impaired listener than the first sound source.

3. The assistive-listening system of claim 1, wherein the support structure positions the second sound source generally above the hearing-impaired listener's head, such that sound is directed generally downward onto the hearing-impaired listener.

4. The assistive-listening system of claim 3, wherein the second sound source is positioned within six inches of the hearing-impaired listener's head without touching the hearing-impaired listener's head.

5. The assistive-listening system of claim 1, further comprising a second volume control configured to change the volume of the second sound source without affecting the volume of the first sound source.

6. A method of assistive-listening for use with sound-producing equipment for listeners, the sound-producing equipment including a signal source and first and second sound sources operatively associated with the signal source and configured to produce sound corresponding to signals received from the signal source, the method comprising:
providing the first sound source for normal-hearing listeners;
providing the second sound source for a hearing-impaired listener, where the second sound source is positioned closer to the hearing-impaired listener than the first sound source;
providing a volume control operatively associated with the signal source and configured to proportionally change the volume of both the first and second sound sources; and
where the second sound source permits the hearing-impaired listener to listen effectively to sound controlled by the volume control without disturbing normal-hearing listeners.
